(19) United States
(12) Patent Application Publication
(10) Pub. No.: US 2015/0129843 A1
(43) Pub. Date: May 14, 2015

(54) ORGANIC LIGHT-EMITTING DIODE DEVICE AND MANUFACTURING METHOD THEREOF

(71) Applicant: SHENZHEN CHINA STAR OPTOELECTRONICS TECHNOLOGY CO., LTD, Shenzhen, Guangdong (CN)

(72) Inventor: Yawei Liu, Shenzhen (CN)

(21) Appl. No.: 14/240,337

(22) PCT Filed: Jan. 22, 2014
(86) PCT No.: PCT/CN2014/071078

§ 371 Date: Feb. 21, 2014

(30) Foreign Application Priority Data
Oct. 21, 2013 (CN) 201310476058.9

(51) Int. Cl. H01L 51/52; H01L 51/00; H01L 27/32; H01L 51/56

(52) U.S. Cl. CPC H01L 51/5243; H01L 51/56; H01L 51/5253; H01L 51/0097; H01L 27/3204; H01L 27/3202; H01L 2251/5338
USPC 257/40; 438/28

(57) ABSTRACT

The present disclosure relates to an organic light-emitting diode (OLED) device and the method for manufacturing the same. The OLED device includes an OLED substrate, on the inner surface of which a plurality of OLEDs are arranged; and a package substrate arranged opposite to the inner surface of the OLED substrate, wherein the OLED substrate and the package substrate are welded and hermetically connected together through a metal solder located therebetween, so that the OLEDs are hermetically packaged between the OLED substrate and the package substrate. In this OLED device, the OLED substrate and the package substrate are hermetically connected together by using the metal solder, so that water and the oxygen can be prevented from entering a sealed area from the exterior, thus prolonging the service life of the OLED device.

### FIELD OF THE INVENTION

The present disclosure relates to a light-emitting diode, in particular to an organic light-emitting diode. The present disclosure also relates to a manufacturing method for the organic light-emitting diode.

### BACKGROUND OF THE INVENTION

Flexible organic light-emitting diode (FOLED) device is increasingly widely used in various electroluminescent apparatuses. This is because the FOLED device has not only the advantages of wide visual angle, high brightness and the like, as in a common organic light-emitting diode (OLED) device, but also the advantage of the substrate of the FOLED device is made of polymer material with good flexibility, whereas the substrate of a common OLED device is generally made of glass. Glass can be bent when the thickness thereof is reduced to 50-200 μm, but it is still impossible to provide a flexibility of being bent in any manner. Meanwhile, thin glass is easy to fracture in use, so that the difficulty of preparation thereof is increased. In comparison, the flexible substrate enables the FOLED device to be thinner and resist higher impact compared with the common OLED device. In addition, the FOLED device is expected to be produced in a roll-to-roll process, so as to greatly reduce the manufacturing cost. Moreover, relative to the glass substrate, the flexible substrate is more suitable to meet the performance requirements of a flexible display in applications.

However, the water and oxygen blocking capability and high-temperature stability of the polymer substrate of the FOLED device are poor. Current packaging methods for the FOLED device, namely “UV glue plus dryer” and “inorganic film”, cannot effectively block water or air, so that an organic functional layer in the FOLED device will be easily damaged due to influence of oxygen and moisture leaked from a surrounding environment, thus shortening the service life of the FOLED device.

### SUMMARY OF THE INVENTION

Aiming at the above-mentioned technical problems in the prior art, the present disclosure proposes an OLED device. An OLED substrate and a package substrate of the OLED device can be hermetically connected to block water vapor and oxygen from entering a sealed area from the exterior, so as to prolong the service life of the OLED device. The present disclosure also relates to a manufacturing method for the OLED device.

1) According to the first aspect of the present disclosure, an OLED device is provided, including: an OLED substrate, on the inner surface of which OLEDs are arranged; and a package substrate arranged opposite to the inner surface of the OLED substrate, wherein the OLED substrate and the package substrate are welded and hermetically connected together through a metal solder located therebetween, so that the OLEDs are hermetically packaged between the OLED substrate and the package substrate.

According to the OLED device of the present disclosure, the OLED substrate and the package substrate are hermetically connected together by using the metal solder. Welding connection provided by the metal solder can effectively block water and oxygen, so as to block water and the oxygen from entering a sealed area from the exterior, thus avoiding damages to the OLEDs and further prolonging the service life of the OLED device. In the context, the term “inner surface” of the OLED substrate indicates a surface thereof facing the package substrate during assembly.

2) In an embodiment of 1) of the present disclosure, the OLED substrate is a flexible substrate. In a preferred example, the OLED substrate is a polymer substrate. The flexible substrate enables the OLED device to be thinner, resist higher impact, and be more suitable for meeting the performance requirements of a flexible display.

3) In an embodiment of 1) or 2) of the present disclosure, the melting point of the metal solder is lower than that of the OLED substrate and that of the package substrate. In a specific example, the metal solder is one or more of tin, tin-bismuth alloy and lead-bismuth alloy. The melting point of the metal solder is lower than that of the polymer substrate, so that the metal solder can be conveniently melted for welding without damaging the polymer substrate.

4) In an embodiment of any of 1) to 3) of the present disclosure, a protective layer is arranged on each of the opposite surfaces of the OLED substrate and the package substrate, and the metal solder is arranged on the protective layer. In a preferred example, an insulating layer is further provided between the protective layer of the OLED substrate and the metal solder. In this case, even if a metal lead is arranged in the protective layer of the OLED substrate, the insulating layer could prevent the metal solder from being connected with the metal lead, which may result in an electricity leakage event. In addition, the insulating layer can also protect the metal lead from being damaged. In an example, the insulating layer is made of one of silicon and silicon dioxide. This inorganic insulating layer will be not damaged during welding the metal solder, so that the yield is improved.

5) According to the second aspect of the present disclosure, a method for manufacturing the above-mentioned OLED device is proposed, including the following steps: providing an OLED substrate, wherein OLEDs are arranged on the inner surface of the OLED substrate; providing a package substrate, which has a mounting region facing the inner surface of the OLED substrate; providing a metal solder on one or both of the inner surface of the OLED substrate and the mounting region of the package substrate; placing the OLED substrate and the package substrate together, with the metal solder contacting with the OLED substrate and the package substrate; and melting the metal solder, so that OLED substrate is hermetically and fixedly connected together with the package substrate after the melted metal solder is cooled.

6) In an embodiment of 5) of the present disclosure, the metal solder is melted by laser. With the use of laser, the welding cost of the OLED device can be effectively reduced, and the welding efficiency is relatively high.

7) In an embodiment of 5) or 6) of the present disclosure, the metal solder is one or more of tin, tin-bismuth alloy and lead-bismuth alloy. These welding materials are readily commercially available at a low price, so that the production cost of the OLED device is relatively low.

8) In an embodiment of 5) to 7) of the present disclosure, a protective layer is arranged on each of the opposite surfaces of the OLED substrate and the package substrate, and the metal solder is arranged on each protective layer.

9) In an embodiment of 5) to 7) of the present disclosure, a protective layer is arranged on each of the opposite surfaces of the OLED substrate and the package substrate, wherein an insulating layer is arranged on the protective layer of the OLED substrate, and the metal solder is arranged on the protective layer of the package substrate corresponding to the insulating layer. In a preferred example, the width of a strip formed by the metal solder is smaller than that of a strip formed by the insulating layer.

Compared with the prior art, the present disclosure has the advantages as follows. According to the OLED device of the present disclosure, the OLED substrate and the package substrate are hermetically connected together by means of metal solder. Welding connection provided by the metal solder can effectively block water and oxygen, so as to block water and the oxygen from entering a sealed area from the exterior, thus avoiding damages to the OLEDs and further prolonging the service life of the FOLED device. In addition, the metal solder is one or more of tin, tin-bismuth alloy and lead-bismuth alloy. The melting point of the metal solder is lower than that of the polymer substrate, so that the metal solder can be conveniently melted for welding without damaging the polymer substrate. And these welding materials are readily commercially available at a low price, so that the production cost of the OLED device is relatively low.

### BRIEF DESCRIPTION OF THE DRAWINGS

The present disclosure will be described in more detail below based on the examples with reference to the accompanying drawings. In the drawings,

FIG. 1 is a schematic diagram of an OLED device according to the present disclosure;

FIG. 2 is a schematic diagram of an OLED substrate according to the present disclosure; and

FIG. 3 is a schematic diagram of a package substrate according to the present disclosure.

In the accompanying drawings, the same components are indicated by the same reference signs. The accompanying drawings are not drawn in actual scale.

### DETAILED DESCRIPTION OF THE EMBODIMENTS

The present disclosure will be further illustrated below in conjunction with the accompanying drawings.

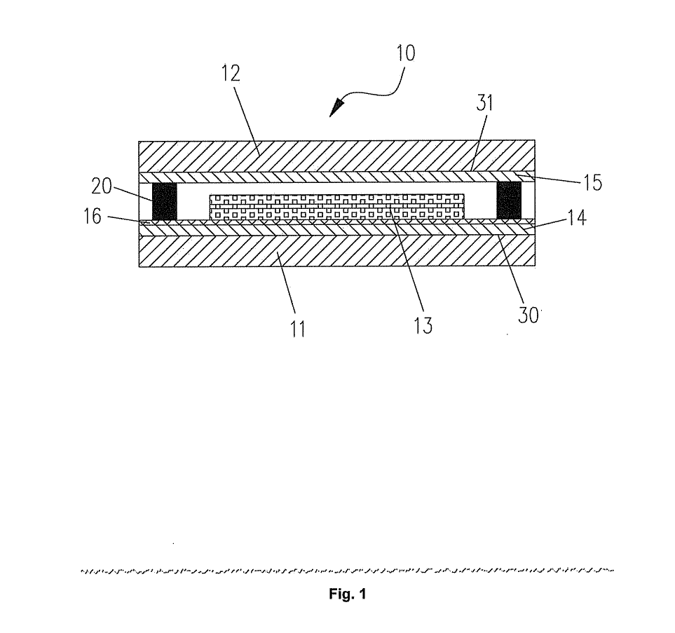

FIG. 1 schematically shows a structure of an organic light-emitting diode (OLED) device 10 (referred to as device 10 below) according to the present disclosure. The device 10 includes a flexible organic light-emitting diode (FOLED) substrate 11, such as a polymer substrate, and OLEDs 13 arranged on the inner surface 30 of the substrate 11. The device 10 further includes a package substrate 12 opposite to the inner surface of the substrate 11. The substrate 11 and the package substrate 12 are welded and hermetically connected together through a metal solder 20 placed therebetween, so that the OLEDs 13 are hermetically packaged between the substrate 11 and the package substrate 12 to form the structure shown in FIG. 1.

Generally, a protective layer (such as a Barix layer known by those skilled in the art) is arranged on each of the opposite surfaces of the substrate 11 and the package substrate 12, such as those indicated by the reference signs 14 and 15 in FIG. 1. Under such a circumstance, the metal solder 20 is arranged between the protective layer 14 and the protective layer 15, and the OLEDs 13 are arranged on the protective layer 14.

Generally, a metal lead (not shown) may be provided in the protective layer 14 of the substrate 11. To avoid electric leakage due to connection of the metal solder 20 and the metal lead, an insulating layer 16 needs to be arranged on the protective layer 14. In this case, the metal solder 20 is arranged above the insulating layer 16, and the OLEDs 13 are arranged on the insulating layer 16, as shown in FIG. 1. In an embodiment, the insulating layer 16 is made of one of silicon and silicon dioxide.

The melting point of the metal solder 20 should be lower than that of the FOLED substrate 11, and also lower than that of the package substrate 12. For example, the metal solder 20 can be one or more of tin, tin-bismuth alloy and lead-bismuth alloy. The melting point of the metal solder 20 is lower than that of the polymer substrate 11. For example, the melting point of tin is 232° C., the melting point of the tin-bismuth alloy is 138° C., the melting point of the lead-bismuth alloy is 120° C., whereas the melting point of the polymer substrate 11 is higher than 250° C. The package substrate 12 can be made of the same material as the polymer substrate 11. In this case, even if the metal solder 20 is melted for welding, the polymer substrate 11 and the package substrate 12 would not be damaged. In addition, to improve the welding efficiency, the metal solder 20 can be melted by laser (not shown). Laser has a very high temperature, and thus can instantaneously melt the metal solder 20. Therefore, the welding efficiency can be significantly improved. Of course, the metal solder 20 may also be melted by other heating methods, which can be optionally selected by those skilled in the art according to actual conditions.

A method for manufacturing the above-mentioned OLED device 10 will be described below.

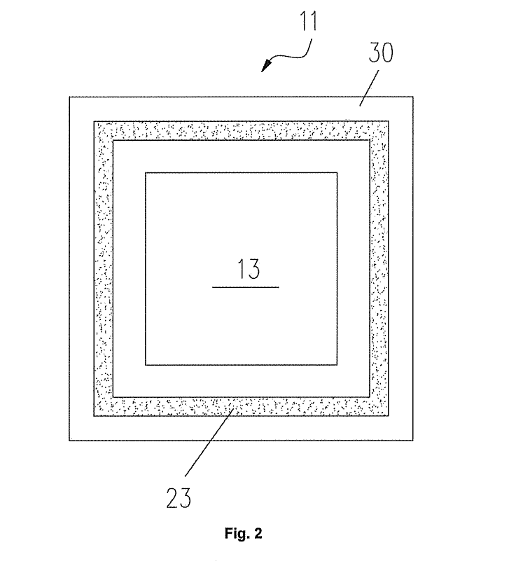

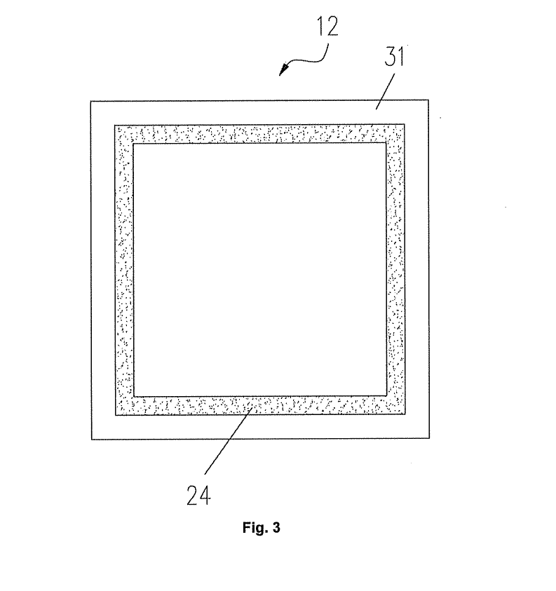

An FOLED substrate 11 is provided. OLEDs 13 are arranged on the inner surface 30 of the substrate 11, as shown in FIG. 2. A package substrate 12 is provided, which includes a mounting region 31 facing the inner surface 30 of the OLED substrate 11, as shown in FIG. 3. A protective layer 14 is further arranged on the inner surface 30 of the substrate 11, and a protective layer 15 is further arranged on the assembly plane 31 of the package substrate 12.

Next, a circle of insulating strip 23, such as a silicon or silicon dioxide strip, is arranged on the protective layer 14 of the substrate 11 in a certain distance, such as 5 mm, away from the edge of the substrate 11. Corresponding to the insulating strip 23, a circle of metal solder strip 24 is arranged on the protective layer 15 of the package substrate 12. To prevent the metal solder from intruding the portion of the substrate 11 where the insulating layer strip 23 is not arranged during the welding process, the width of the metal solder strip 24 is selected as being smaller than that of the insulating layer strip 23. To arrange the metal solder strip 24 on the protective layer 15, a metal solder sinter may be pre-formed by metal solder powder on the protective layer 15 through powder metallurgy technology. In another manner, the metal solder strip can be obtained through mixing metal solder powder with an organic solvent of a certain viscosity, such as ethanol, into paste, coating the resulted paste on the protective layer 15, and then volatilizing the organic solvent. The metal solder strip can be also obtained through forming the metal solder into a strip similar to a conductive tape, and then affixing the resulted strip to the protective layer 15 of the package substrate 12.

The mounting region 31 of the package substrate 12 is arranged opposite to the inner surface 30 of the OLED substrate 11, and the metal solder strip 24 is superposed to the insulating layer strip 23. The metal solder is melted by laser, and after the melted metal solder is cooled, the OLED substrate 11 is hermetically and fixedly connected together with the package substrate 12. Therefore, the OLEDs 13 are hermetically packaged.

Although in the above example the metal solder strip is formed on the package substrate 12, it could be understood that the metal solder strip may be formed on the insulating layer strip 23 of the OLED substrate 11 instead, or alternatively, formed on both of the package substrate 12 and the insulating layer strip 23.

Although the present disclosure has been described with reference to the preferred embodiments, various modifications could be made to the present disclosure without departing from the scope of the present disclosure and components in the present disclosure could be substituted by equivalents. Particularly, as long as structural conflicts do not exist, all technical features mentioned in all the embodiments may be combined together in any mode. The present disclosure is not limited to the specific embodiments disclosed in the description, but includes all technical solutions falling into the scope of the claims.

1. An organic light-emitting diode device, including:
an organic light-emitting diode substrate, on the inner surface of which a plurality of organic light-emitting diodes are arranged; and
a package substrate arranged opposite to the inner surface of the organic light-emitting diode substrate,
wherein the organic light-emitting diode substrate and the package substrate are welded and hermetically connected together through a metal solder located therebetween, so that the organic light-emitting diodes are hermetically packaged between the organic light-emitting diode substrate and the package substrate.

2. The organic light-emitting diode device according to claim 1, wherein the melting point of the metal solder is lower than that of the organic light-emitting diode substrate and that of the package substrate.

3. The organic light-emitting diode device according to claim 2, wherein the metal solder is one or more of tin, tin-bismuth alloy and lead-bismuth alloy.

4. The organic light-emitting diode device according to claim 2, wherein a protective layer is arranged on each of the opposite surfaces of the organic light-emitting diode substrate and the package substrate, and the metal solder is arranged on the protective layer.

5. The organic light-emitting diode device according to claim 4, wherein an insulating layer is further provided between the protective layer of the organic light-emitting diode substrate and the metal solder.

6. The organic light-emitting diode device according to claim 5, wherein the insulating layer is made of one of silicon and silicon dioxide.

7. The organic light-emitting diode device according to claim 2, wherein the organic light-emitting diode substrate is a flexible substrate.

8. The organic light-emitting diode device according to claim 7, wherein the organic light-emitting diode substrate is a polymer substrate.

9. A method for manufacturing the organic light-emitting diode device according to claim 2, including the following steps:
providing an organic light-emitting diode substrate, on the inner surface of which a plurality of organic light-emitting diodes are arranged;
providing a package substrate, which has a mounting region facing the inner surface of the organic light-emitting diode substrate;
providing a metal solder on one or both of the inner surface of the organic light-emitting diode substrate and the mounting region of the package substrate;
placing the organic light-emitting diode substrate and the package substrate together, with the metal solder contacting with the organic light-emitting diode substrate and the package substrate; and
melting the metal solder, so that organic light-emitting diode substrate is hermetically and fixedly connected together with the package substrate after the melted metal solder is cooled.

10. The method according to claim 9, wherein the metal solder is one or more of tin, tin-bismuth alloy and lead-bismuth alloy.

11. The method according to claim 9, wherein a protective layer is arranged on each of the opposite surfaces of the organic light-emitting diode substrate and the package substrate, and the metal solder is arranged on the protective layer.

12. The method according to claim 9, wherein a protective layer is arranged on each of the opposite surfaces of the organic light-emitting diode substrate and the package substrate, wherein an insulating layer is arranged on the protective layer of the organic light-emitting diode substrate, and the metal solder is arranged on the protective layer of the package substrate corresponding to the insulating layer.

13. The method according to claim 12, wherein the width of a strip formed by the metal solder is smaller than that of a strip formed by the insulating layer.

14. The method according to claim 12, wherein the metal solder is melt by laser.
